(19) United States
(12) Patent Application Publication
(10) Pub. No.: US 2007/0045662 A1
(43) Pub. Date: Mar. 1, 2007

(54) SUBSTRATE FOR FILM GROWTH OF GROUP III NITRIDES, METHOD OF MANUFACTURING THE SAME, AND SEMICONDUCTOR DEVICE USING THE SAME

(75) Inventors: Shigeaki SUMIYA, Nagoya-shi (JP); Tomohiko SHIBATA, Nagoya-shi (JP); Masahito MIYASHITA, Tokyo (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignees: DOWA MINING CO., LTD., Tokyo (JP); NGK INSULATORS, LTD., Nagoya-shi (JP)

(21) Appl. No.: 11/467,319

(22) Filed: Aug. 25, 2006

(30) Foreign Application Priority Data
Aug. 26, 2005 (JP) 2005-246852

(51) Int. Cl. H01L 31/00

(52) U.S. Cl. 257/189

(57) ABSTRACT

A substrate for film growth of group III nitride, a method of manufacturing the same, and a semiconductor device using the same are provided which can make an AlN thin film relatively thin without cloudiness, as well as cracks and pits are reduced in a group III nitride thin film layer constituting the device grown thereon.

A substrate 10 for film growth of group III nitride is constituted which includes a substrate material 11 and an AlN thin film 12 formed on said substrate as a buffer layer, and a semiconductor device comprising group III nitride thin film is formed thereon, and the AlN thin film is formed at plural steps at least one of which changes film growth conditions during the film growth.

### FIELD OF THE INVENTION

The present invention relates to a substrate for film growth of, for example, Group III nitrides, a method of manufacturing the same, and semiconductor devices using the same.

### BACKGROUND OF THE INVENTION

When the substrates for film growth for film-formation of, for example, semiconductor devices are manufactured, a buffer layer of AlN (aluminum nitride) or GaN (gallium nitride) has so far been formed by MOCVD (Metal Organic Chemical Vapor Deposition) method or MBE (Molecular Beam Epitaxy) method on a substrate such as sapphire substrate. Here, for film growth of such a buffer layer, so-called low temperature buffer layer technique is disclosed in the Japanese Laid-Open Patent Publication, for example, H02-229476 A (1990)(Patent Reference 1) and others. So-called AlN direct high temperature growth techniques are disclosed in the Japanese Laid-Open Patent Publications such as JP H09-64477 A (1997)(Patent Reference 2), JP 2001-135854 A (Patent Reference 3), JP 2003-45899 A (Patent Reference 4), and JP 2002-367917 A (Patent Reference 5) etc.

According to the low temperature buffer layer technique disclosed in Patent Reference 1, substrates for film growth are manufactured that the buffer layer of GaN or others is grown onto the sapphire substrate to the thickness of several nm to about 100 nm under the temperature condition of, for example, about 400 to 600° C. by using MOCVD method.

A semiconductor device can be manufactured by film growth of thin film layers consisting of a Group III nitride thin film constituting the semiconductor device on the buffer layer of the thus manufactured substrate for film growth at temperature of, for example, about 1000° C.

However, in such a low temperature buffer layer technique, the grown buffer layer is amorphous containing fine crystals. When later the temperature is increased to about 1000° C. for film growth of the device structure, it differs considerably from the film growth temperature of said buffer layer, and hence the buffer layer becomes polycrystalline and contains relatively large amount of dislocations inside. Therefore, with respect to a device structure, since a large amount of dislocations are formed as the threading dislocations from said dislocations, and the crystalline quality is widely dispersed and cracks tend to occur because of the low crystal quality.

On the other hand, according to said AlN direct high temperature growth technique of, for example, Patent Reference 5, substrates for film growth are manufactured that the buffer layer of GaN or others is grown onto on the sapphire substrate to the thickness of about 1 to 2 μm at the temperature condition of, for example, about 1000 to 1250° C. by similarly using MOCVD method,

A semiconductor device can be manufactured by film growth of thin film layers constituting the semiconductor device on the buffer layer of the thus manufactured substrate at the temperature of, for example, about 1000° C.

### SUMMARY OF THE INVENTION

Here in said AlN direct high temperature growth technique of Patent Reference 5, though cracks do not practically occur, the film thickness of this buffer layer can not be made 0.5 μm or less in order to maintain flatness on the atomic level with regard to the surface of AlN thin film as the buffer layer. Therefore, it is difficult to form thin film, as well as the substrate tends to warp due to the lattice constant difference of the buffer layer and the substrate, since the thickness of the buffer layer is 0.5 μm or more. In addition, there is a problem that, since a large amount of materials to form the buffer layer is necessary, the manufacturing cost of the substrate with the buffer layer attached thereon is high.

There is also a problem that, though cracks do not easily occur, so-called pits tend to occur, and if the film growth temperature of the buffer layer is high, cloudiness tends to occur in the grown AlN thin film.

In view of the problems mentioned above, it is an object of the present invention to provide a substrate for film growth of Group III nitrides, a method of manufacturing the same, and semiconductor devices using the same which can form a relatively thin AlN thin film without causing cloudiness, as well as can make less cracks and pits in the group III nitride thin film layer constituting devices grown thereon.

The object mentioned above can be attained, according to the first aspect of the present invention, by a substrate for group III nitride film growth, characterized in that it is a substrate for film growth of group III nitride with a semiconductor device comprising a group III nitride thin film formed thereon, including a substrate material, and AlN system thin film as a buffer layer formed on said substrate, said AlN system thin film is formed at plural steps to change film growth condition by at least once during film growth, and the pit density is 2×10⁸ cm⁻² or less.

In said aspect, the substrate for film growth of group III nitride in accordance with the present invention is preferably such that the parameters of said change in film growth conditions are a growth temperature, a pressure, or source gases flow rates, its flow rate ratio, and a timing of change.

Preferably, the substrate is either of a sapphire substrate, a SiC (silicon carbide) substrate, and Si (silicon) substrate. In this case, the substrate surface is preferably made nitride. Also the AlN system thin film is preferably formed by change of the film growth condition non-step-wise in at least a part of the film growth time. Still also preferably, the AlN system thin film is AlN thin film. As a preferred aspect, C-plane group III nitride is grown.

According to first aspect mentioned above, by forming the AlN thin film at plural steps of mutually different parameters of film growth conditions, for example, the growth temperature, the pressure, or the source gases flow rates, its flow rate ratio, and the timing of change of growth conditions, the single crystal AlN thin film is formed on the substrate such as, for example, the sapphire substrate, the SiC substrate, and the Si substrate, cloudiness of AlN thin film can be avoided, as well as the film can be made thinner, and the dislocation density of AlN thin film is lowered, so that the pit generation density is lowered in the device structure formed on the AlN thin film, and thereby occurrence of cracks can be reduced.

In case that the AlN thin film is formed by changing film growth conditions non-step-wise in at least a part of film growth time, the AlN film is formed as a practically continuously changing infinitive step.

The object mentioned above can be attained, according to the second aspect of the present invention, by a method of manufacturing a substrate for film growth of group III nitride for growing a semiconductor device comprising a group III nitride thin film thereon by forming AlN system thin film on a substrate as a buffer layer, by which AlN system thin film is formed at plural steps to change film growth condition by at least once in course of film formation.

In said aspect, the substrate is preferably either of a sapphire substrate, a SiC substrate, and Si substrate. In this case, the substrate surface is made nitride.

According to the second aspect mentioned above, by forming AlN system thin film at plural steps by changing parameters of film growth conditions, for example, a growth temperature, a pressure, or source gases flow rates, its flow rate ratio, and a timing of change of growth conditions, the single crystal AlN system thin film is formed on the substrate such as, for example, a sapphire substrate, a SiC substrate, and a Si substrate, at least once during film growth, cloudiness of the AlN system thin film can be avoided, as well as the film can be made thinner, and the dislocation density of AlN system thin film is lowered, so that the pit generation density is lowered in the device structure formed on AlN system thin film, and thereby occurrence of cracks can be reduced.

In said aspect, the parameters of the change in film growth conditions are a growth temperature, a pressure, or source gases flow rates, its flow rate ratio, and a timing of change of growth conditions. According to said aspect, the film growth time can be made as short as possible as a whole.

The AlN system thin film may be formed by change of the film growth conditions non-step-wise in at least a part of film growth time. According to said aspect, the AlN system film is formed as a practically continuously changing infinitive step.

Among film growth conditions, the film growth temperature may be changed as gradually rising at each step. Preferably, among film growth conditions, the film growth time is changed as longer at each step. Also preferably, among film growth conditions, the V/III ratio is changed as smaller at each step.

In any case that, among said film growth conditions, the film growth temperature is changed as gradually rising at each step, the film growth time is changed as longer at each step, or the V/III ratio is changed as smaller at each step, the generated pit density is more reduced, and the AlN system thin film surface can be formed flat.

Upon changing film growth conditions, the film growth of AlN system thin film may be temporarily interrupted. According to said aspect, the change of film growth conditions, especially the change of the V/III ratio of source gases can be conducted assuredly during interruption.

Upon changing film growth conditions, film growth of AlN system thin film may be conducted continuously without temporary interruption. According to said aspect, the film growth time can be made as short as possible as a whole. Also preferably, the AlN system thin film is the AlN thin film.

According to the third aspect of the present invention, the object mentioned above can be attained by a semiconductor device characterized to be constituted by using a substrate for said film growth of group III nitride, or by using a substrate for said film growth of group III nitride manufactured by the above-mentioned method, and forming the thin film of a device structure of a semiconductor device on said substrate for film growth of group III nitride.

In said aspect, the device structure of a semiconductor device is such a semiconductor light emitting device as a light emitting diode, a laser diode, and others. The device structure of a semiconductor device is also preferably an electronic device such as an FET.

According to said third aspect, since a device structure as semiconductor light emitting devices such as a light emitting diode and a laser diode, and electronic devices such as FET and others is formed onto AlN system thin film of the substrate for film growth of group III nitride using the substrate mentioned above for film growth of group III nitride, the generated pit density of thin film is lowered in said device structure, and thereby occurrence of cracks can be reduced.

According to the present invention, the substrate for film growth of group III nitride and the method of manufacturing the same are provided which can make AlN system thin film relatively thin, formed without cloudiness, as well as cracks and pits are reduced in number in a group III nitride thin film layer constituting a device growing thereon. Also by reducing occurrence of cracks and pits in AlN system thin film, the crystalline quality of a group III nitride film formed on AlN system thin film is more stabilized, and can be made higher quality.

According to the present invention, in the substrate for film growth of group III nitride thin film such as GaN, AlN and others to constitute a device structure of a semiconductor device, by forming the AlN system thin film as the buffer layer formed on its surface at plural steps of mutually different film growth conditions, said AlN system thin film is made relatively thin without cloudiness, as well as cracks and pits are reduced in number in the group III nitride thin film layer constituting said AlN system thin film growing thereon.

### BRIEF DESCRIPTION OF THE DRAWINGS

FIG. 1 is a cross-sectional view diagrammatically illustrating the structure of one embodiment of a substrate for film growth of group III nitride in accordance with the present invention,

FIG. 2 is a graph diagrammatically illustrating AlN thin film on the substrate for film growth of group III nitride of FIG. 1.

FIG. 3 is a block diagram illustrating a constitution of an embodiment of a manufacturing apparatus to manufacture the substrate for film growth of group III nitride as shown in FIG. 1.

FIG. 4 shows a temperature diagram during the film growth process of the AlN thin film by the manufacturing apparatus of FIG. 3.

FIG. 5 is a diagrammatical cross-sectional view illustrating the constitution of the first embodiment of a semiconductor device with a device structure formed on the substrate for film growth of group III nitride of FIG. 1.

FIG. 6 is a diagrammatical cross-sectional view illustrating the constitution of the second embodiment of a semiconductor device with a device structure formed on the substrate for film growth of group III nitride of FIG. 1.

FIG. 7 is a diagrammatical cross-sectional view illustrating the constitution of the third embodiment of a semiconductor device with a device structure formed on the substrate for film growth of group III nitride of FIG. 1.

FIG. 8 is a graph showing the pit density on the AlN thin film surface formed on the substrate for film growth of group III nitride in Example 1.

FIG. 9 is an image of an atomic force microscope (AFM) of AlN thin film surface formed on the substrate for film growth of group III nitride in Example 1-1 and Comparative Example 1-1.

FIG. 10 is a graph showing the pit density of AlN thin film formed on the substrate for film growth of group III nitride in Example 2.

FIG. 11 is a graph showing the pit density on AlN thin film surface formed on the substrate for film growth of group III nitride in Example 3.

FIG. 12 is a graph showing the pit density on AlN thin film surface formed on the substrate for film growth of group III nitride in Example 4.

FIG. 13 is a graph showing the film thickness ratio of the first and the second steps of the AlN thin film of the substrate for film growth of group III nitride in Example 4, and the range where the lowering effect of pit density is especially high.

### DETAILED DESCRIPTION OF THE PREFERRED EMBODIMENT

Hereinafter, the embodiment of the present invention is explained in detail with reference to figures.

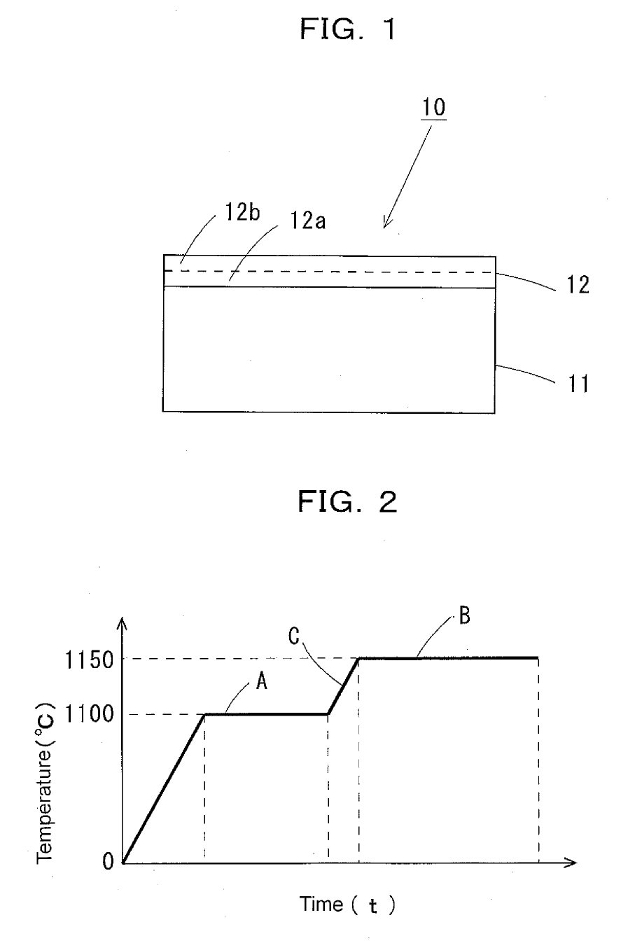

FIG. 1 is a cross-sectional view diagrammatically illustrating the structure of a substrate for film growth of group III nitride in accordance with the present invention. In FIG. 1, a substrate 10 for film growth of group III nitride comprises a substrate 11 and an AlN thin film 12 as a buffer layer formed on the surface of the substrate material 11. In the embodiment of the present invention, an explanation is made of the case of forming the AlN thin film 12 as an AlN system thin film on the substrate material 11. Here, the AlN system thin film is defined as a thin film made of a group III nitride material in which Al (aluminum) is most of all group III elements, about 8% or more of them.

As said substrate material 11, either substrate selected from, for example, a sapphire substrate, a SiC substrate, Si substrate, and others is used. AlN thin film 12 is, in this case, formed as AlN thin film 12a and 12b, respectively, at plural steps of mutually different film growth conditions, at two steps as shown by dotted lines in the illustrated case. In case of the sapphire substrate, a plane to form AlN thin film may be plane a or plane c.

Here as the parameters of changing film growth conditions, a film growth temperature, a pressure, a flow rate source gases, and a molar ratio of the group III element and group V element in the source gases (hereinafter, to be properly called merely V/III ratio or flow rate ratio) and timing of film growth condition change are possible. For example, the AlN thin film may be formed at plural steps changing film growth conditions at least once during film growth. Also, the MN thin film may be formed changing film growth conditions non-step-wise in at least a part of its film growth time. Among film growth conditions, the film growth temperature may be changed gradually higher at each step. The film growth time may be changed longer at each step.

Among film growth conditions, in case that the formed film is a III-V compound semiconductor, the ratio of group III element (group III element such as Ga and Al) and group V element (Group V element such as N and As), that is, V/III ratio may be changed smaller at each step. Also, upon changing film growth conditions, the AlN thin film growth may be temporarily interrupted.

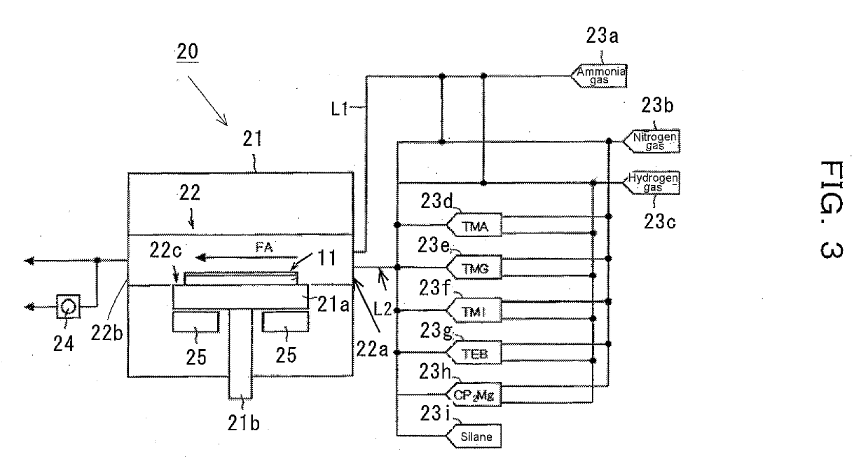

FIG. 2 is a graph diagrammatically illustrating an example of the AlN thin film on the substrate material for film growth of group III nitride of FIG. 1. As shown in FIG. 2, in case to change film growth temperature during film growth, the AlN thin film 12 is formed at a first step A at the film growth temperature of 1100° C., and then the AlN thin film 12 is formed at a second step B in a middle course at the film growth temperature of 1150° C.

Here, the film growth interruption period C may be set between the above-mentioned first step A and the second step B. In this case, during the film growth interruption period C, a change of a temperature or a pressure and change of feed gas can be conducted assuredly. Then, the film growth interruption period C is set at preferable time, for example, 10 or 60 seconds, depending upon film growth conditions, and during interruption period, the atmosphere may better be the mixed gas of NH₃ and a carrier gas or a carrier gas. The mixed gas atmosphere of TMA and the carrier gas is not preferred because it causes many pits.

A manufacturing apparatus for manufacturing such a substrate 10 for film growth of group III nitride is constituted, for example, as shown in FIG. 3.

FIG. 3 is a block diagram illustrating a constitution of an embodiment of the manufacturing apparatus to manufacture the substrate for film growth of group III nitride as shown in FIG. 1. In FIG. 3, the manufacturing apparatus 20 is the apparatus to form the AlN thin film 12 on the substrate material 11, that is, a so-called MOCVD apparatus using a group III group organometallic gas and a gas containing nitrogen element as a source gas, and growing the group III nitride thin film by a chemical vapor reaction method. In this case, the manufacturing apparatus 20 is designed so as to flow the source gas for growing the AlN thin film 12 onto the principal surface of the substrate material 11.

Here, said manufacturing apparatus 20 is used not only for AlN thin film growth, but is constituted so that a single or multi layer structure onto the pre-determined substrate material can be epitaxially grown, and thereby a device structure of a semiconductor device using various group III nitride materials can be formed.

Said manufacturing apparatus 20 is provided with a reactive gas introducing tube 22 inside a reactor vessel 21, and said reactive gas introducing tube 22 has an introducing inlet 22a, an exhausting outlet 22b, and an open hole part 22c. The source gas is introduced from said introducing inlet 22a into the reactive gas introducing tube 22, and exhausted from said exhausting outlet 22b. In this case, since said open hole part 22c faces the principal surface of the substrate material 11 housed inside the reactor vessel 21, the source gas can contact the principal surface of said substrate material 11.

Piping systems L1 and L2 are connected to said introducing inlet 22a. Here, the piping system L1 is connected to the supply sources 23a, 23b, and 23c of, for example, ammonia gas (NH₃) as a source gas, and the nitrogen gas (N₂) and the hydrogen gas (H₂) as carrier gases, and supplies these gases.

On the other hand, the piping system L2 is that for supplying, for example, TMA (trimethyl aluminum; Al(CH₃)₃), TMG (trimethyl gallium; Ga(CH₃)₃), TMI (trimethyl indium; In(CH₃)₃), TEB (triethyl boron; B(C₂H₅)₃), CP₂Mg (cyclopentadienyl magnesium; Mg(C₅H₅)₂), and silane gas (SiH₄) as source gases, and the nitrogen gas and the hydrogen gas as carrier gases.

Further, the supply sources 23d to 23i of TMA, TEB, TMG, TMI, CP₂Mg, and silane gas as the source gases for the formation of epitaxial substrate and device are connected to the piping system L2.

Here, since said CP₂Mg and silane gas are the source materials of Mg and Si as acceptors and donors in a group III nitride, respectively, the source gases can be properly changed depending upon the acceptors and the donors to be used. Also, in order to conduct so-called bubbling, the supply sources 23d to 23h of said TMA, TEB, TMG, TMI, CP₂Mg are connected to the supply sources of nitrogen gas 23b and hydrogen gas 23c, respectively.

Further in said manufacturing apparatus 20, hydrogen gas, nitrogen gas, or the mixture gases thereof functions as the carrier gas, and gas flow rates are measured by flow meters, and are properly controlled at all the gas supply sources 23a to 23i. By such control of gas flow rates, group III nitrides having various mixed crystal composition are epitaxially grown onto the substrate material 11.

On the other hand, a vacuum pump 24 is connected to said exhausting outlet 22b to forcibly exhaust the gas inside the reactor vessel 21, and to attain the reduced pressure atmosphere to the pre-determined pressure.

Said reactor vessel 21 is provided with a susceptor 21a for setting the substrate material 11 therein and supporting legs 21b for supporting said susceptor 21a inside the reactor vessel 21.

The susceptor 21a is heated by a heater 25 provided right thereunderneath, and is controlled to the pre-determined temperature.

Here, the heater 25 is, for example, made of resistance or high frequency induction heating and the epitaxial growth temperature can be adjusted by controlling the temperature of the susceptor 21a closely attached to the substrate material 11. Namely, the epitaxial growth temperature by using MOCVD method of the manufacturing apparatus 20 is controlled by the heater 25.

By using such manufacturing apparatus 20, it is possible to form the AlN thin film 12 on the above-mentioned substrate 10 for film growth of group III nitride by plural steps, properly adjusting the film growth temperature, the pressure, source gases flow rates and its flow rate ratio, and the timing of change of film growth conditions during film growth. In this case, the conditions can be set so the growth film thickness becomes step-wise in such a way that a film is formed thin at the first step, and sequentially thicker from the second step.

In this case, the film growth temperature can be adjusted by controlling the heater 25. Also, the pressure inside the reactor vessel 21 can be adjusted by controlling the vacuum pump 24.

Further, the flow rates of source gases and the flow rate ratios can be adjusted by utilizing the flow meters provided to respective supply sources 23a to 23i.

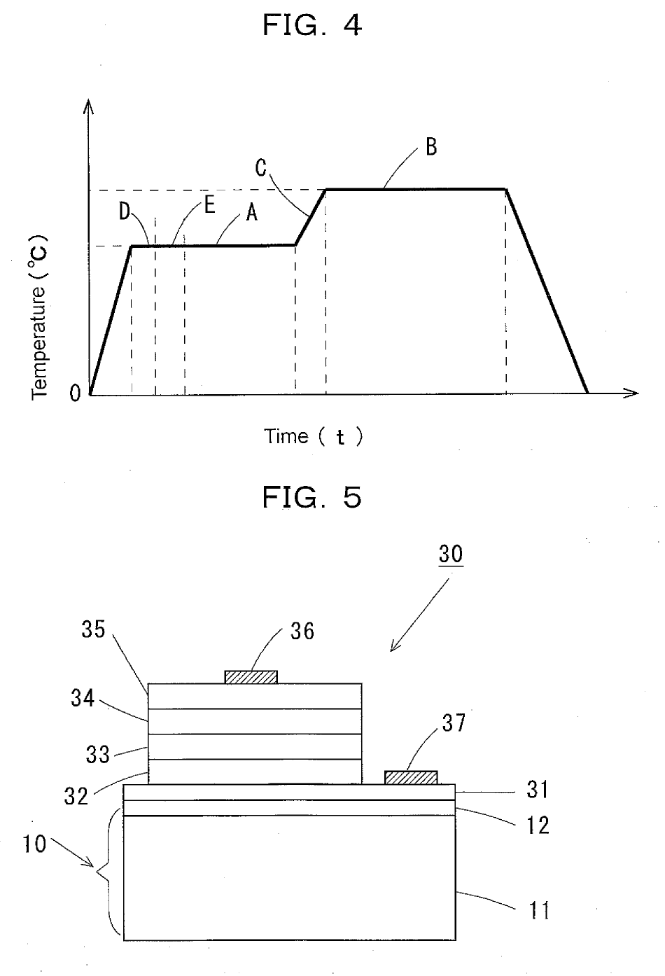

FIG. 4 shows a temperature diagram during the film growth process of the AlN thin film in the manufacturing apparatus of FIG. 3. As shown in FIG. 4, the substrate material 11 is set on a susceptor 21a inside the reactor vessel 21 of the manufacturing apparatus 20, the reactor vessel 21 is evacuated by the vacuum pump 24, and the substrate material 11 is heated by the heater 25, followed by cleaning D with hydrogen gas and nitrifying E of the surface of the substrate material 11. After that, at said first step A and second step B, the AlN thin film 12 is grown by two steps. Thereby, the substrate material 11 for film growth of group III nitride is completed. In this case, the growth initiation temperature of the first step A is preferably the predetermined temperature, for example, 1100° C. or higher. A film of good quality could not be obtained at lower than this temperature.

According to the present invention, the substrate for film growth of group III nitride and the method of manufacturing the same can be offered by which the AlN thin film can be formed relatively thin, for example, 0.5 μm or less without cloudiness, as well as cracks and pits are made less in group III nitride thin film layer constituting devices grown thereon and others.

A semiconductor device using said substrate material 11 for film growth of group III nitride will be explained next. The semiconductor device using said substrate material 11 for film growth of group III nitride of the present invention may be any semiconductor device that can be formed on said substrate. As such a semiconductor device, various diodes, various transistor, integrated circuits including these active devices and passive parts such as resistances and capacitors may be mentioned.

FIG. 5 illustrates the second structural example of a semiconductor device with its device structure constituted with group III nitride film on said substrate 10 for film growth of group III nitride.

In FIG. 5, the semiconductor device 30 is such an light emitting diode that a first contact layer 31, a first cladding layer 32, a light emitting layer 33, a second cladding layer 34, and a second contact layer 35 are sequentially grown onto the substrate 10 for film growth of group III nitride shown in FIG. 1, and electrodes 36 and 37 are formed in the partially exposed first and second contact layers In this case, since the AlN thin film 12 of the substrate material 11 for film growth of group III nitride is formed flat by atomic level with low dislocation density, the pit density in the device structure of the light emitting diode 30 formed thereon is markedly lowered, and no crack is generated, thereby the quality of the light emitting diode (LED) 30 is improved,

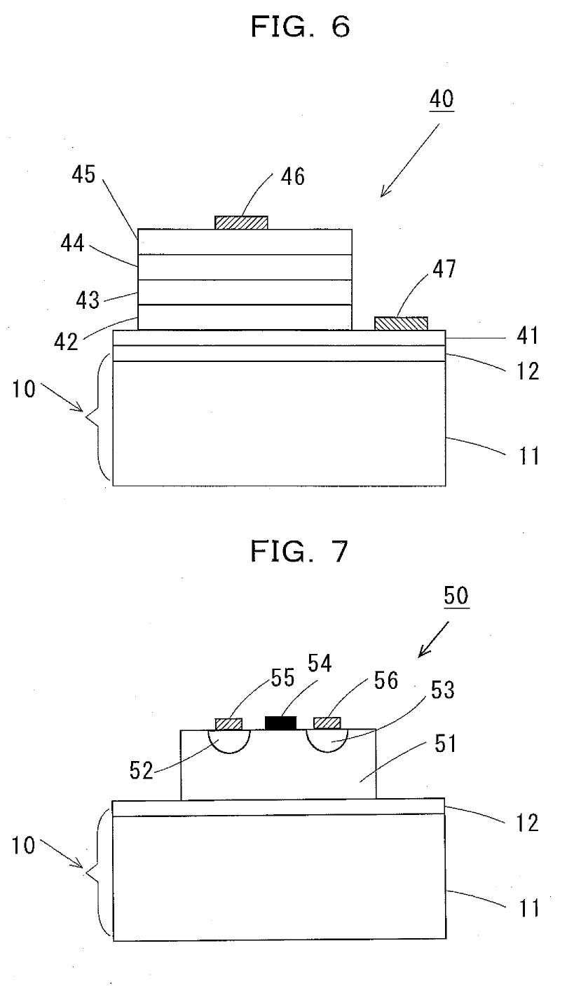

FIG. 6 illustrates the second structural example of a semiconductor device with its device structure constituted with group III nitride film on said substrate material 11 for film growth of group III nitride.

In FIG. 6, the semiconductor device 40 is such a semiconductor laser diode that a first contact layer 41, a first cladding layer 42, an active layer 43, a second cladding layer 44, and a second contact layer 45 are sequentially grown onto the substrate 10 for film growth of group III nitride shown in FIG. 1, and electrodes 46 and 47 are formed in the partially exposed first and second contact layers.

In this case, since the AlN thin film 12 of the substrate 10 for film growth of group III nitride is formed flat by atomic level with low dislocation density, the pit density in the device structure of the semiconductor laser diode 40 formed thereon is markedly lowered, and no crack is generated, thereby the quality of the semiconductor laser diode (LD) 40 is improved.

FIG. 7 illustrates the third structural example of a semiconductor device with its device structure constituted with group III nitride film on said substrate material 11 for film growth of group III nitride.

In FIG. 7, the semiconductor device 50 is such that an FET structure is constituted therein by forming a channel layer 51 formed on the substrate 10 for film growth of group III nitride shown in FIG. 1, a source region 52 and a drain region 53 formed in the channel layer 51 by an ion implantation method or others, a Schottky electrode 54, a source electrode 55, and a drain electrode 56.

In this case, since the AlN thin film 12 of the substrate 10 for film growth of group III nitride is formed flat by atomic level at low dislocation density, the pit density in the channel layer 51 constituting the FET 50 layered thereon is markedly lowered, and no crack is generated, thereby the quality of the FET 50 is improved.

### EXAMPLE 1

Hereinafter, the present invention is explained in more detail referring to the examples.

The method of manufacturing the substrate material 11 for film growth of group III nitride of the present invention will be explained first.

As a substrate material 11, a (0001) plane sapphire single crystal of 2 inch diameter and 400 μm thickness. Table 1 is a table showing each film growth condition in Examples 1-4 of manufacturing the substrate for film growth of group III nitride by using the manufacturing apparatus of FIG. 3.

[Table 1]

In each Example, after setting the pressure in the reactor vessel 21 of the manufacturing apparatus 20 to 15 Torr, the hydrogen gas was flown as the carrier gas at 350 milli mole (mmole)/minute, and the substrate material 11 was treated for cleaning by heating at a pre-determined temperature, and next the surface of the substrate material 11 was treated for making nitride by supplying ammonia gas. After that, a first layer AlN thin film 12a and a second layer AlN thin film 12b of the AlN thin film 12 were formed by supplying TMA and ammonia gas.

In Example 1, after cleaning with hydrogen gas at 1200° C. for 10 minutes and treating for making nitride at 1200° C. for 5 minutes, the growing parameters are set to constant as the pressure of 15 Torr, the group III source amount 35 (μmole/minute), the group V source amount 4.5 (mmole/minute), the V/III ratio (source gases flow rate ratio) 130 (4.5 mmole/35 μmole), and carrier gas feed amount 350 (mmole/minute). Then, as the first step, the AlN thin film 12a of film thickness 0.3 μm was formed at film growth temperature 1200° C. and as the second step the AlN thin film 12b of film thickness 0.3 μm was grown to form AlN thin film 12 at growth temperature changed as 1200° C., 1225° C., 1250° C., 1400° C., and 1500° C. (to be called Comparative example 1-1, and Examples 1-1 to 1-4, respectively).

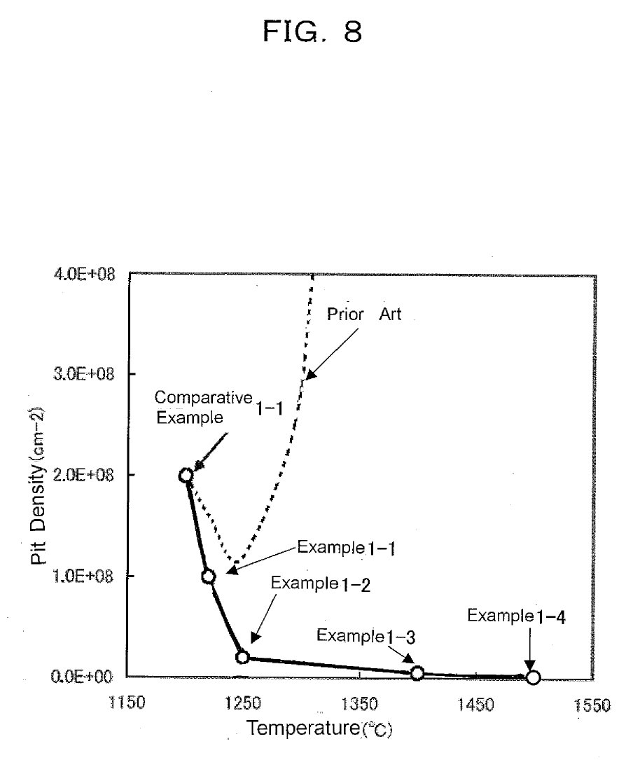

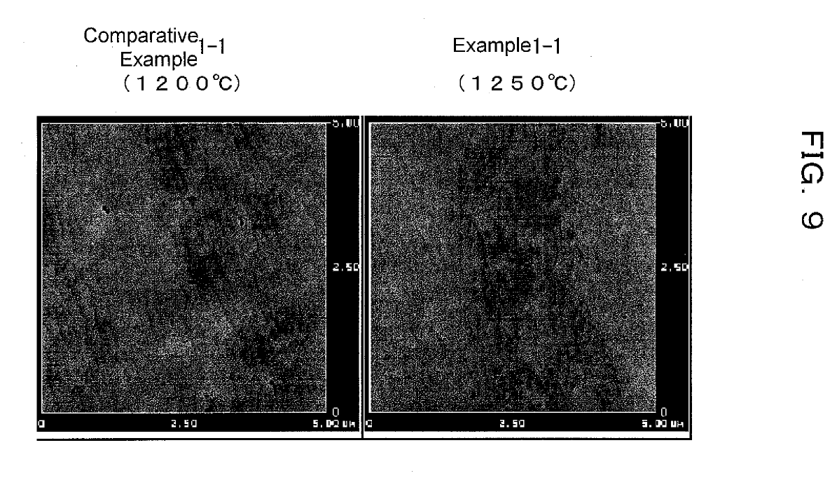

FIG. 8 is a graph showing the pit density on the AlN thin film surface formed on the substrate for film growth of group III nitride in Example 1. In the figure, the etch pit densities are illustrated with marks ◯ for Examples 1-1 to 1-4 and Comparative Example 1-1, and the data of prior art is illustrated with a broken line. The prior art of the broken line is the case of the first step of the film growth conditions without interruption and any change for continuous growth, that is, the method of continuous growth under single condition at high temperature.

As is shown in FIG. 8, the pit densities of Examples 1-1-1-4 are lowered to 1×10⁸/cm² or less, showing marked improvement of etch pit density compared with Comparative Example 1-1 and the prior art.

FIG. 9 is an image of an atomic force microscope (AFM) of AlN thin film surface formed on the substrate for film growth of group III nitride in Example 1-1 and Comparative Example 1-1. As is shown in FIG. 9, the surface of the AlN thin film of Example 1-1 is obvious as flat compared with that of Comparative Example 1-1.

### EXAMPLE 2

Example 2 will be explained next.

In Example 2, after treating for cleaning with hydrogen gas at 1100° C. for 10 minutes and treating for making nitride at 1100° C. for 10 seconds, the growing parameters are set to constant as the pressure of 10 Torr, the film growth temperature 1100° C., and carrier gas feed amount 350 (mmole/minute). As the first step, the film thickness of 0.3 μm was grown with the parameters as the group III source amount 35 (μmole/minute), the group V source amount 4.5 (mmole/minute), and V/III ratio (source gas flow rate ratio) 130. As the second step, the film thickness of 0.3 μm was grown to form the AlN thin film 12 with the parameters as the group III source amount changed as 35, 17.5, 52.5, 35, and 35 (μ mole/minute), accompanied by the change of group V source amount as 4.5,4.5,4.5,9.0, and 1.8 (mmole/minute), and the change of V/III ratio (source gas flow rate ratio) as 130, 260, 86, 260 and 50 (to be called Examples 2-1 to 2-5, respectively).

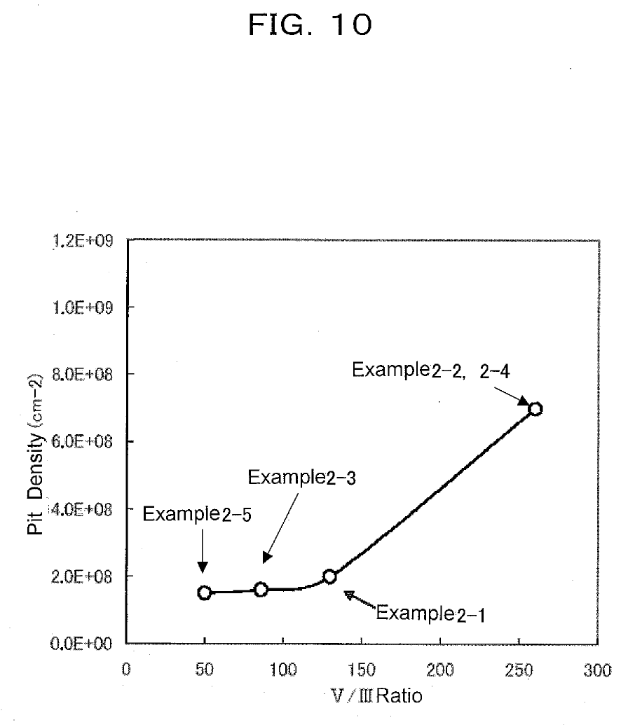

FIG. 10 is a graph showing the pit density of the AlN thin film formed on the substrate for film growth of group III nitride in Example 2. As is shown in FIG. 10, the pit density (/cm²) of the AlN thin film surface is confirmed to be improved to 2×10⁸/cm² or less in Example 2-3 (V/III=86) and Example 2-5 (V/II=50) in which V/III ratio is lower at the second step B than at the first step A (V/III=130). Therefrom, it was recognized that the pit density can be lowered when the V/III ratio as the film growth condition is changed lower at the second step B.

### EXAMPLE 3

Example 3 will be explained next.

In Example 3, after cleaning with hydrogen gas at 1100° C. for 10 minutes and treating for making nitride at 1100° C. for 7 minutes, the growth parameters are set to constant as the film growth temperature 1100° C., the group III source amount 40 (μmole/minute), the group V source amount 20 (mmole/minute), V/III ratio (source gas flow rate ratio) 500, and carrier gas feed amount 350 (mmole/minute). As the first step the AlN thin film 12 of film thickness 0.3 μm was formed at pressure 15 Torr, and at a second step the film thickness of 0.3 μm was grown to form the AlN thin film as the pressures changed to 8, 10, 15, and 20 Torr (to be called Examples 3-1 to 3-5, respectively).

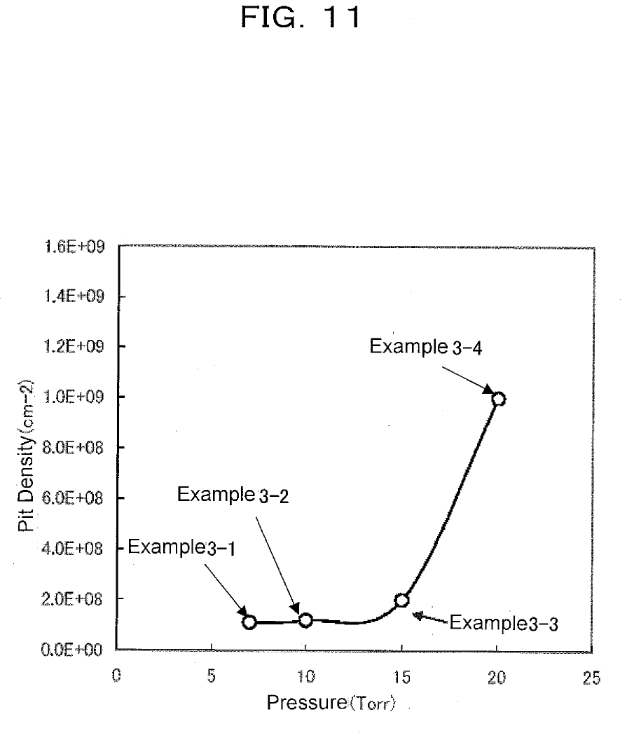

FIG. 11 is a graph showing the pit density of the AlN thin film surface formed on the substrate for film growth of group III nitride in Example 3. As is shown in FIG. 11, the pit density (/cm²) of the AlN thin film surface is confirmed to be improved to 2×10⁸/cm² or less in Example 3-1 (pressure at the second step is 8 Torr) and Example 3-2 (pressure at the second step is 10 Torr) in which the pressure at the second step is lower than at the first step (pressure is 15 Torr). Therefrom, it was recognized that the pit density can be lowered when pressure is changed lower at the second step B.

Here, in Example 3, the case is described where the pressure was changed from 8 to 20 Torr, but it is not limited to this, and the similar effects were obtained in case of change from 5 to 100 Torr.

### EXAMPLE 4

Example 4 will be explained next.

In Examples 4-1 to 4-3, after cleaning with hydrogen gas at 1200° C. for 10 minutes and treating for making nitride at 1200° C. for 3 minutes, the growth parameters are set to constant as the pressure 8 Torr, the group III source amount 35 (μmole/minute), the group V source amount 4.5 (mmole/minute), the V/III ratio (source gases flow rate ratio) 130, and carrier gas feed amount 350 (mmole/minute). As the first step, the film growth temperature was set to 1200° C. and and the film thicknesses was arranged to 0.2, 0.3, and 0.4 μm. As the second step, the film growth temperature was set to 1250° C. and the AlN thin films 12 were formed having the thicknesses of 0.4, 0.3, and 0.2 μm, respectively.

As Comparative Example 4-1, after cleaning with hydrogen gas at 1250° C. for 10 minutes and treating for making nitride at 1250° C. for 3 minutes, the AlN thin film 12 was formed with constant film growth conditions of the pressure 8 Torr, the film growth temperature 1250° C., the film thickness 0.6 μm, the group III source amount 35 (μmole/minute), the group V source amount 4.5 (mmole/minute), V/III ratio (source gas flow rate ratio) 130, and carrier gas feed amount 350 (mmole/minute).

As Comparative Example 4-2, after cleaning with hydrogen gas at 1200° C. for 10 minutes and treating for making nitride at 1200° C. for 3 minutes, the AlN thin film 12 was formed with constant film growth conditions of the pressure 8 Torr, the film growth temperature 1200° C., the film thickness 0.6 μm, the group III source amount 35 (μmole/minute), the group V source amount 4.5 (mmole/minute), V/III ratio (source gas flow rate ratio) 130, and carrier gas feed amount 350 (mmole/minute).

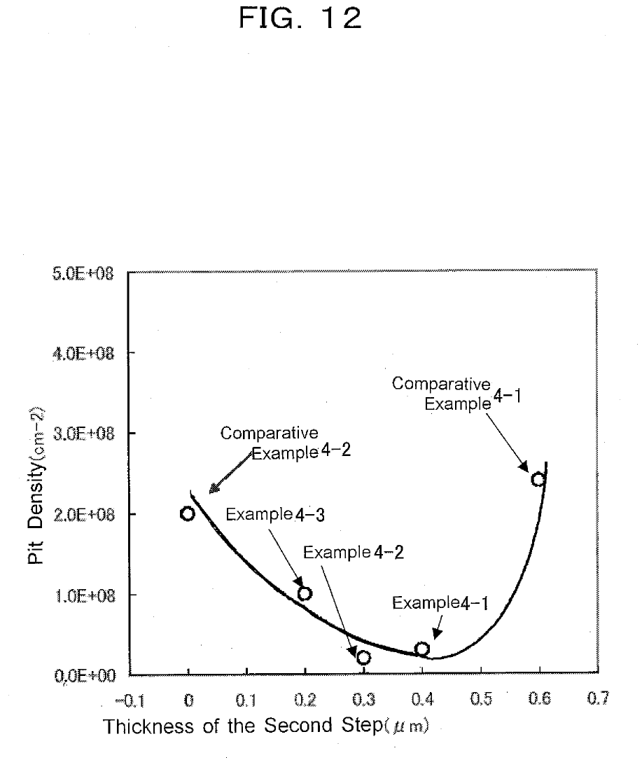

FIG. 12 is a graph showing the pit density of the AlN thin film surface formed on the substrate for film growth of group III nitride in Example 4. As is shown in FIG. 12, the pit densities (/cm²) of the AlN thin film surface are recognized to be improved to 2×10⁸/cm² or less in Examples 4-1 to 4-3 compared with those of the results of two Comparative examples 4-1 and 4-2 as prior arts. Here, in case of the initial film growth temperature 1250° C. (Comparative Example 4-1), the cloudiness was confirmed in the AlN thin film 12.

Here in Experiment 4 mentioned above, the case was shown in which the total film thickness of AlN thin film 12 is 0.6 μm, but it is not limited, and the similar effect was also obtained in cases of total film thicknesses 0.2, 0.4, 0.8, and 1.0 μm by changing film thickness ratio of AlN thin films 12a and 12b at pressure 30 Torr, and V/III ratio 200, and at the first step film growth temperature 1150° C. and the second step film growth temperature 1250° C.

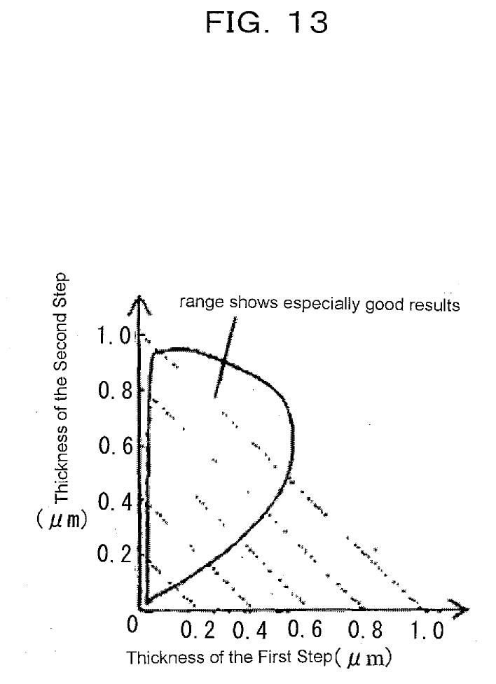

FIG. 13 is a graph showing the film thickness ratio of the first and the second steps of the AlN thin film of the substrate for film growth of group III nitride in Example 4, and the range where the lowering effect of pit density is especially high. As is shown in FIG. 13, the second step film (12b) thickness turned out to have especially high pit lowering effect in the region surrounded with a solid line, that is, where the second step film thickness is made thicker than the first step film (12a) thickness.

It is needless to say the present invention is not limited to the Examples described above, but various modifications are possible within the range of the invention as set forth in the claims, and these are also included in the range of the invention. In the embodiments mentioned above, a film growth interruption period C is set between the first step A and the second step B, but, in case that, for example, the film growth conditions are changed continuously (at infinitive steps) at the second step B from that at the first step A after the first step A, the film growth interruption period C can be omitted because the distribution of the film growth conditions is small. It is also possible to form film by simultaneously change, for example, all three factors among the film growth conditions of AlN system thin film, arbitrarily selecting the factors of film growth temperature, time, and V/III ratio.

| | | | | Growth Conditions | | | | | | | | | | | | | |
|---|---|---|---|---|---|---|---|---|---|---|---|---|---|---|---|---|---|
| | | | | | | | | | | III group | | V group | | | | Feed | |
| | | | | | | | | | | source | | source | | | | Amount of | |
| | | | | Pressure | | Temperature | | Thickness | | amount | | amount | | | | Carrier Gas | |
| | | Hydrogen | Nitifi- | (Torr) | | (° C.) | | (μm) | | (μmol/min) | | (μmol/min) | | V/III ratio | | (mmol/min) | |
| | | Cleaning | cation | step 1 | step 2 | step 1 | step 2 | step 1 | step 2 | step 1 | step 2 | step 1 | step 2 | step 1 | step 2 | step 1 | step 2 |
| Exaple | Example 1-1 | 1200° C. | 1200° C. | 15 | 15 | 1200 | 1225 | 0.3 | 0.3 | 35 | 35 | 4.5 | 4.5 | 130 | 130 | 350 | 350 |
| 1 | Example 1-2 | 10 min. | 5 min. | | | | 1250 | | | | | | | | | | |
| | Example 1-3 | | | | | | 1400 | | | | | | | | | | |
| | Example 1-4 | | | | | | 1500 | | | | | | | | | | |
| | Comparative | | | | | | 1200 | | | | | | | | | | |
| | Example 1-1 | | | | | | | | | | | | | | | | |
| Exaple | Example 2-1 | 1100° C. | 1100° C. | 10 | 10 | 1100 | 1100 | 0.3 | 0.3 | 35 | 35 | 4.5 | 4.5 | 130 | 130 | 350 | 350 |
| 2 | Example 2-2 | 10 min. | 10 sec. | | | | | | | | 17.5 | | 4.5 | | 260 | | |
| | Example 2-3 | | | | | | | | | | 52.5 | | 4.5 | | 86 | | |
| | Example 2-4 | | | | | | | | | | 35 | | 9.0 | | 260 | | |
| | Comparative | | | | | | | | | | 35 | | 1.8 | | 50 | | |
| | Example 2-5 | | | | | | | | | | | | | | | | |
| Exaple | Example 2-1 | 1100° C. | 1100° C. | 15 | 8 | 1100 | 1100 | 0.3 | 0.3 | 40 | 40 | 20 | 20 | 500 | 500 | 350 | 350 |
| 3 | Example 2-2 | 10 min. | 7 min. | | 10 | | | | | | | | | | | | |
| | Example 2-3 | | | | 15 | | | | | | | | | | | | |
| | Example 2-4 | | | | 20 | | | | | | | | | | | | |
| Exaple | Comparative | 1250° C. | 1250° C. | 8 | 8 | | 1250 | 0 | 0.6 | 35 | 35 | 4.5 | 4.5 | 130 | 130 | 350 | 350 |
| 4 | Example 4-1 | 10 min. | 3 min. | | | | | | | | | | | | | | |
| | Example 4-1 | 1200° C. | 1200° C. | | | 1200 | 1250 | 0.2 | 0.4 | | | | | | | | |
| | Example 4-2 | 10 min. | 3 min. | | | 1200 | 1250 | 0.3 | 0.3 | | | | | | | | |
| | Example 4-3 | | | | | 1200 | 1250 | 0.4 | 0.2 | | | | | | | | |
| | Example 4-4 | | | | | 1200 | | 0.6 | 0 | | | | | | | | |

1. A substrate for film growth of group III nitride, including a substrate material, and AlN system thin film formed on said substrate material as a buffer layer, characterized in that:
a semiconductor device comprising group III nitride thin film is formed thereon,
said AlN system thin film is formed at plural steps at least one of which changes film growth conditions during film growth, and
its pit density is 2×10⁸ cm² or less.

2. The substrate for film growth of group III nitride as set forth in claim 1, characterized in that the parameters of said film growth condition change are a growth temperature, a pressure, or source gases flow rates and its flow rate ratio, and a timing of change of growth conditions.

3. The substrate for film growth of group III nitride as set forth in claim 1, characterized in that said substrate material is either a sapphire substrate, a SiC substrate or a Si substrate.

4. The substrate for film growth of group III nitride as set forth in claim 3, characterized in that the surface of said substrate is treated for making nitride.

5. The substrate for film growth of group III nitride as set forth in claim 1, characterized in that said AlN system thin film is formed by changing film growth conditions non-stepwise at least in a part of film growth time.

6. The substrate for film growth of group III nitride as set forth in claim 1, characterized in that said AlN system thin film is AlN thin film.

7. A method of manufacturing a substrate for film growth of group III nitride to grow a semiconductor device comprising a group III nitride thin film thereon by forming AlN system thin film on a substrate as a buffer layer, characterized in that:
said AlN system thin film is formed at plural steps at least one of which changes film growth conditions during film growth.

8. The method of manufacturing a substrate for film growth of group III nitride as set forth in claim 7, characterized in that the parameters of said film growth condition change are a growth temperature, a pressure, or gases flow rates and its flow rate ratio, and a timing of change of growth conditions.

9. The method of manufacturing a substrate for film growth of group III nitride as set forth in claim 7, characterized in that said substrate is either a sapphire substrate, a SiC substrate, or a Si substrate.

10. The method of manufacturing a substrate for film growth of group III nitride as set forth in claim 9, characterized in that the surface of said substrate is treated for making nitride.

11. The method of manufacturing a substrate for film growth of group III nitride as set forth in claim 7, characterized in that said AlN system thin film is formed by changing film growth conditions non-stepwise at least in a part of film growth time.

12. The method of manufacturing a substrate for film growth of group III nitride as set forth in claim 7, characterized in that the film growth temperature, among said film growth conditions, is changed as gradually higher at each step.

13. The method of manufacturing a substrate for film growth of group III nitride as set forth in claim 7, characterized in that the film growth time, among said film growth conditions, is changed as gradually longer at each step.

14. The method of manufacturing a substrate for film growth of group III nitride as set forth in claim 7, characterized in that V/III ratio, among said film growth conditions, is changed as gradually smaller at each step.

15. The method of manufacturing a substrate for film growth of group III nitride as set forth in claim 7, characterized in that film growth of AlN system thin film is temporarily interrupted during said film growth condition change.

16. The method of manufacturing a substrate for film growth of group III nitride as set forth in claim 7, characterized in that film growth of AlN system thin film is continuously conducted uninterrupted during said film growth condition change.

17. The method of manufacturing a substrate for film growth of group III nitride as set forth in claim 7, characterized in that said AlN system thin film is AlN thin film.

18. A semiconductor device, characterized in that:
it is constituted by using a substrate for film growth of group III nitride including a substrate material, and AlN system thin film formed on said substrate material as a buffer layer, characterized in that a semiconductor device comprising group III nitride thin film is formed thereon; said AlN system thin film is formed at plural steps at least one of which changes film growth conditions during film growth, and its pit density is 2×10⁸ cm² or less, or
by using a substrate for film growth of group III nitride manufactured by growing a semiconductor device comprising a group III nitride thin film thereon by forming AlN system thin film on a substrate as a buffer layer, characterized in that said AlN system thin film is formed at plural steps at least one of which changes film growth conditions during film growth, and
by forming a thin film of device structure of a semiconductor device on said substrate for film growth of group III nitride.

19. The semiconductor device as set forth in claim 18, characterized in that said device structure of a semiconductor device is a semiconductor light emitting device such as a light emitting diode and a laser diode.

20. The semiconductor device as set forth in claim 18, characterized in that said device structure of a semiconductor device is an electronic device such as an FET.
